(19) United States
(12) Patent Application Publication
(10) Pub. No.: US 2014/0251410 A1
(43) Pub. Date: Sep. 11, 2014

(54) PHOTOVOLTAIC ENERGY PANEL

(71) Applicant: GREENCELL ENERGY LTD, (US)

(72) Inventor: Haim SHAHAR, Kiryat Haim (IL)

(73) Assignee: GREENCELL ENERGY LTD, Klryat Haim (IL)

(21) Appl. No.: 13/784,855

(22) Filed: Mar. 5, 2013

(51) Int. Cl. H01L 31/05; H01L 31/02

(52) U.S. Cl. CPC H01L 31/0508; H01L 31/02021
USPC 136/246; 136/256

(57) ABSTRACT

A photovoltaic energy panel has first and second electrically conductive regions on first and second sides of an electrically insulating sheet. Each of at least some pairs of the first electrically conductive regions are connected electrically by a photovoltaic cell between the two members of the pair. The panel also includes vias, each of which electrically connects one of the first electrically conductive regions to one of the second electrically conductive regions. There are first and electrical contacts, at first and second edges of the sheet, each of which is directly or indirectly connected to one of the electrically conductive regions. The electrically conductive regions, the cells and the vias are arranged to provide an electrically conductive path between one of the first contact and one, two or more of the second contacts.

### FIELD AND BACKGROUND OF THE INVENTION

The present invention relates to photovoltaic energy panels and, more particularly, to a photovoltaic energy panel based on an innovative electrical circuit.

Background information on photovoltaic energy panels may be found in the following US patent documents:

U.S. Pat. No. 3,369,939 to Myer

U.S. Pat. No. 3,427,200 to Lapin et al.

U.S. Pat. No. 3,574,925 to Schneider et al.

U.S. Pat. No. 4,023,368 to Kelly

U.S. Pat. No. 4,088,121 to Lapeyre

U.S. Pat. No. 4,089,705 to Rubin

U.S. Pat. No. 4,166,917 to Dorfeld et al.

U.S. Pat. No. 4,174,978 to Lidorenko et al.

U.S. Pat. No. 4,350,836 to Crouthamel et al.

U.S. Pat. No. 4,367,367 to Reisfeld et al.

U.S. Pat. No. 5,374,317 to Lamb et al.

U.S. Pat. No. 6,493,342 to Bechtel et al.

U.S. Pat. No. 7,161,083 to Mortenson

U.S. Pat. No. 8,067,295 to Yagiura et al.

U.S. Pat. No. 2012/0024345 to Reisfeld et al.

All of these patent documents are incorporated by reference for all purposes as if fully set forth herein.

Moslehi, in U.S. Pat. No. 8,035,028, which also is incorporated by reference for all purposes as if fully set forth herein, teaches a photovoltaic energy panel based on thin film solar cells that are mounted on a printed circuit board. FIG. 1 is FIG. 59 of the Moslehi patent and shows an array 980 of thin film solar cells 982 connected in series and connecting an input lead 984 to an output lead 986. Array 980 is mounted on a printed circuit board. FIG. 2 is FIG. 60 of the Moslehi patent and shows the upper surface 990 of the printed circuit board, with electrically conductive solid squares 992 and electrically conductive hollow squares 994. FIG. 3 is FIG. 61 of the Moslehi patent and shows the lower surface 1000 of the printed circuit board with electrically conductive regions that are connected to squares 992 and 994, by vias that are represented by small circles, to provide the series connection that is illustrated in FIG. 1.

FIG. 4 illustrates the principle of concentration of solar energy by a luminescent solar concentrator 10. Luminescent solar concentrator 10 is a transparent glass or plastic plate that is doped with luminophores 12. A photovoltaic cell 14 is mounted on the side of concentrator 10. Luminophores 12 absorb incident solar radiation 16 at wavelengths that are too short for cell 14 to convert efficiently to direct current (DC) electricity and re-radiate the radiation at wavelengths that cell 14 converts more efficiently to DC electricity. Concentrator 10 acts as a waveguide that conveys the re-radiated radiation, as well as directly incident radiation 16, to cell 14.

A sufficient number of breaks in the electrical connections from upper surface 990 of Moslehi's printed circuit board to lower surface 1000 of Moslehi's printed circuit board, for example in the vias that connect one of hollow squares 994 to the corresponding electrically conductive region on lower surface 1000, can render array 980 inoperative. Moslehi states, without showing explicitly how, that solar cells 982 can be connected in a mixed series-parallel circuit, which presumably would be more robust against such failures that the strictly series circuit of FIGS. 1-3; but a sufficient number of breaks in the electrical connections to input lead 984 or output lead 986 still would render such a serial-parallel array of solar cells 982 inoperative. It would be highly advantageous to have a photovoltaic energy panel that is more robust against failure than the photovoltaic energy panels of Moslehi.

### SUMMARY OF THE INVENTION

According to the present invention there is provided an electrical device including: (a) an electrically insulating sheet; (b) on a first side of the sheet: (i) a plurality of first electrically conductive regions that are electrically isolated from each other, and (ii) for each of at least a portion of adjacent pairs of the first electrically conductive regions: a respective electrical component that electrically connects the first electrically conductive regions of the each pair; (c) on a second side of the sheet, a plurality of second electrically conductive regions that are electrically isolated from each other; (d) a plurality of vias through the sheet, each via electrically connecting one respective the first electrically conductive region to one the second electrically conductive region; (e) at least one first electrical contact, at a first edge of the sheet, electrically connected to one of the electrically conductive region; and (f) a plurality of second electrical contacts at a second edge of the sheet, each second electrical contact being electrically connected to one of the electrically conductive regions; wherein the electrically conductive regions, the components and the vias are arranged to provide an electrically conductive path between each first electrical contact and at least two of the second electrical contacts.

According to the present invention there is provided a photovoltaic energy panel including: (a) an electrically insulating sheet; (b) on a first side of the sheet: (i) a plurality of first electrically conductive regions that are electrically isolated from each other, and (ii) for each of at least a portion of adjacent pairs of the first electrically conductive regions: a respective photovoltaic cell, between the first electrically conductive regions of the each pair, that electrically connects the first electrically conductive regions of the each pair; (c) on a second side of the sheet, a plurality of second electrically conductive regions that are electrically isolated from each other; (d) a plurality of vias through the sheet, each via electrically connecting one respective the first electrically conductive region to one the second electrically conductive region; (e) at least one first electrical contact, at a first edge of the sheet, electrically connected to one of the electrically conductive region; and (f) at least one IS second electrical contact at a second edge of the sheet, electrically connected to one of the electrically conductive regions; wherein the electrically conductive regions, the photovoltaic cells and the vias are arranged to provide an electrically conductive path between each first electrical contact and at least one of the at least one second electrical contact.

According to the present invention there is provided a photovoltaic energy panel including: (a) a substantially flat substrate; (b) at least one photovoltaic cell embedded in the substrate; (c) an optically transparent layer covering at least a portion of the substrate; and (d) for each photovoltaic cell, a respective lens for directing, towards the each photovoltaic cell, light that emerges from the optically transparent layer.

A basic embodiment of an electrical device is based on an electrically insulating sheet. On a first side of the sheet there is a plurality of first electrically conductive regions that are electrically isolated from each other. For at least some adjacent pairs of such first electrically conductive regions, there is a respective electrical component, such as a photovoltaic cell, that electrically connects the two members of the pair. On a second side of the sheet there is a plurality of second electrically conductive regions that are electrically isolated from each other. Through the sheet there are vias, each one of which electrically connects one of the first electrically conductive regions to one of the second electrically conductive regions. There is at least one electrical contact, at a first edge of the sheet (i.e., off to the side of the electrically conductive regions on that side of the sheet), that is electrically connected to one of the electrically conductive regions, either directly to one of the electrically conductive regions on that side of the sheet or by a via to one of the electrically conductive regions on the other side of the sheet. There is a plurality of electrical contacts, at a second edge of the sheet (i.e., off to the side of the electrically conductive regions on that side of the sheet), each of which is electrically connected to one of the electrically conductive regions, either directly to one of the electrically conductive regions on that side of the sheet or by a via to one of the electrically conductive regions on the other side of the sheet. The electrically conductive regions, the components and the vias are arranged to provide an electrically conductive path between each first electrical contact and at least two of the second electrical contacts.

Preferably, the device includes a plurality of first electrical contacts.

Preferably, if the components are photovoltaic cells, each cell is between the two first electrically conductive regions that are electrically connected by the cell. Also, if the components are photovoltaic cells, the device preferably also includes an optically transparent layer that covers at least a portion of the first electrically conductive regions on the first side of the sheet, and also includes, for each cell, a respective lens for directing, towards that cell, light that emerges from the optically transparent layer. Most preferably, such a device also includes a diffusely reflective layer, that at least partially covers the first electrically conductive regions, between the first side of the sheet and the optically transparent layer. Also most preferably, the transparent layer includes a luminescent solar concentrator.

A basic embodiment of a photovoltaic energy panel is based on an electrically insulating sheet. On a first side of the sheet there is a plurality of first electrically conductive regions that are electrically isolated from each other. At least some adjacent pairs of such first electrically conductive regions have, between the two members of the pair, a respective photovoltaic cell that electrically connects the two members of the pair. On a second side of the sheet there is a plurality of second electrically conductive regions that are electrically isolated from each other. Through the sheet there are vias, each one of which electrically connects one of the first electrically conductive regions to one of the second electrically conductive regions. There is at least one electrical contact, at a first edge of the sheet (i.e., off to the side of the electrically conductive regions on that side of the sheet), that is electrically connected to one of the electrically conductive regions, either directly to one of the electrically conductive regions on that side of the sheet or by a via to one of the electrically conductive regions on the other side of the sheet. There is at least one electrical contact, at a second edge of the sheet (i.e., off to the side of the electrically conductive regions on that side of the sheet), that is electrically connected to one of the electrically conductive regions, either directly to one of the electrically conductive regions on that side of the sheet or by a via to one of the electrically conductive regions on the other side of the sheet. The electrically conductive regions, the cells and the vias are arranged to provide an electrically conductive path between each first electrical contact and (at least one of) the second electrical contact(s).

Preferably, the panel also includes an optically transparent layer that covers at least a portion of the first electrically conductive regions on the first side of the sheet, and also includes, for each cell, a respective lens for directing, towards that cell, light that emerges from the optically transparent layer. Most preferably, such a panel also includes a diffusely reflective layer, that at least partially covers the first electrically conductive regions, between the first side of the sheet and the optically transparent layer. Also most preferably, the transparent layer includes a luminescent solar concentrator.

Another basic photovoltaic energy panel includes a substantially flat substrate, one or more photovoltaic cells embedded in the substrate, an optically transparent layer that covers at least a portion of the substrate, and, for each cell, a respective lens that directs, towards the cell, light that emerges from the optically transparent layer.

Preferably, the optically transparent layer includes a luminescent solar concentrator.

Preferably, the panel also includes a diffusely reflective layer between the substrate and the optically transparent layer.

### BRIEF DESCRIPTION OF THE DRAWINGS

Various embodiments are herein described, by way of example only, with reference to the accompanying drawings, wherein:

FIG. 1 shows a solar panel of the prior art that includes an array of thin film solar cells mounted on a printed circuit board;

FIG. 2 shows the upper surface of the printed circuit board of the solar panel of FIG. 1;

FIG. 3 shows the lower surface of the printed circuit board of the solar panel of FIG. 1;

FIG. 4 illustrates the principle of concentration of solar energy by a luminescent solar concentrator;

FIGS. 5 and 6 are cross-sections of small portions of two different photovoltaic panels of the present invention;

FIG. 7 shows the layout of the upper conductors of a basic photovoltaic panel of the present invention;

FIGS. 8A and 8B show the layout of the lower conductors of a basic photovoltaic panel of the present invention;

FIGS. 9A and 9B show a portion of the layout of a typical full-size photovoltaic panel of the present invention.

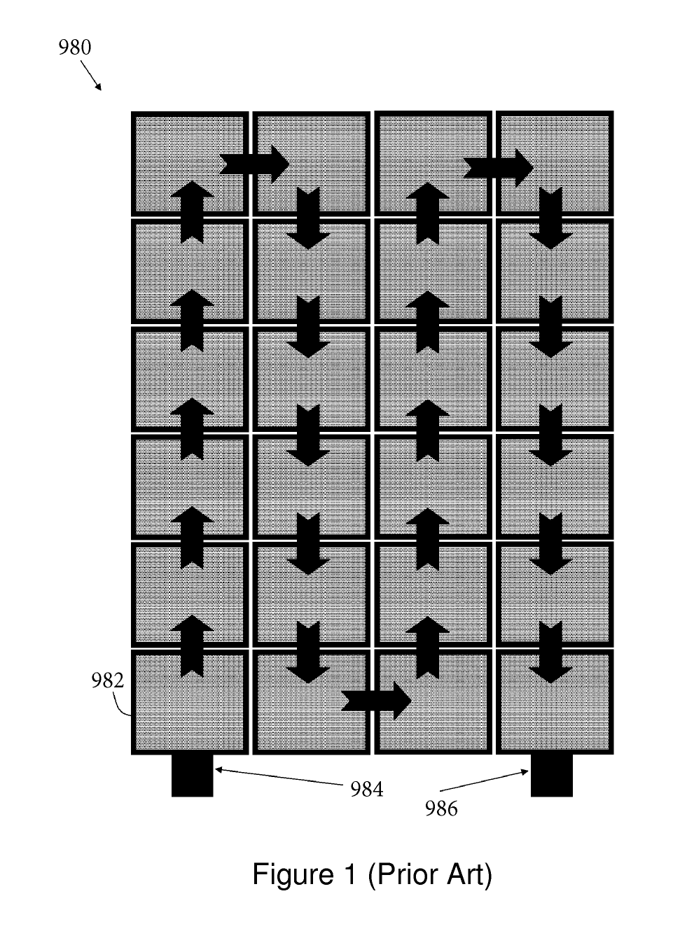

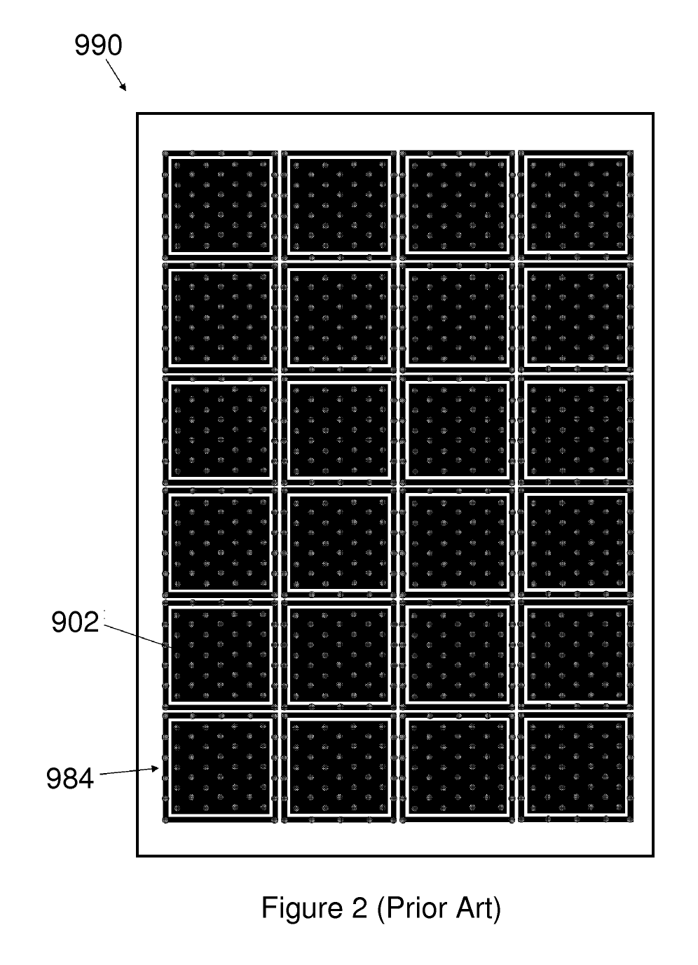

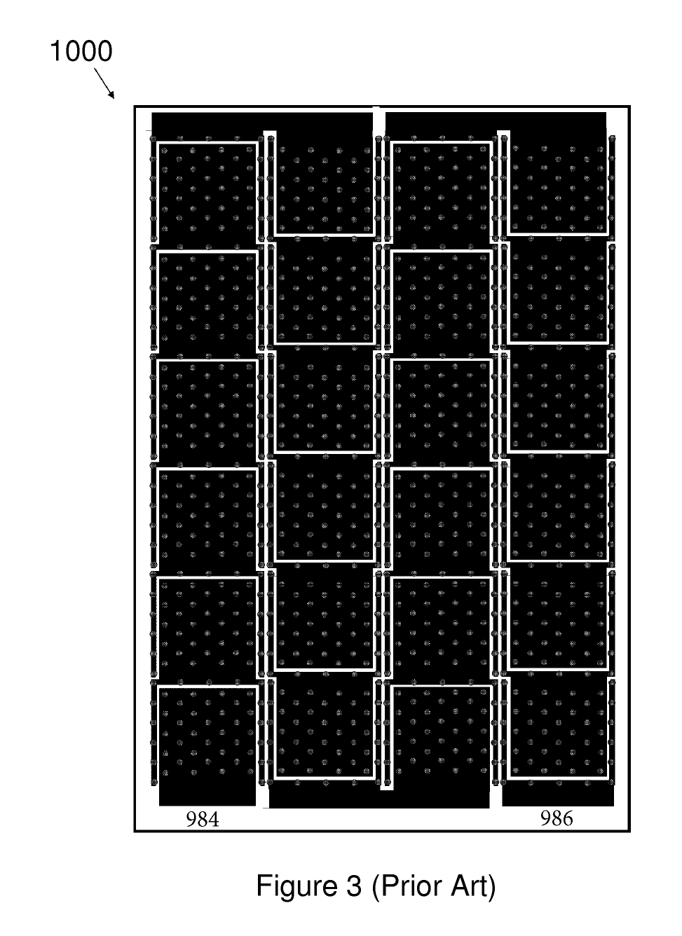

### DESCRIPTION OF THE PREFERRED EMBODIMENTS

The principles and operation of a photovoltaic panel according to the present invention may be better understood with reference to the drawings and the accompanying description.

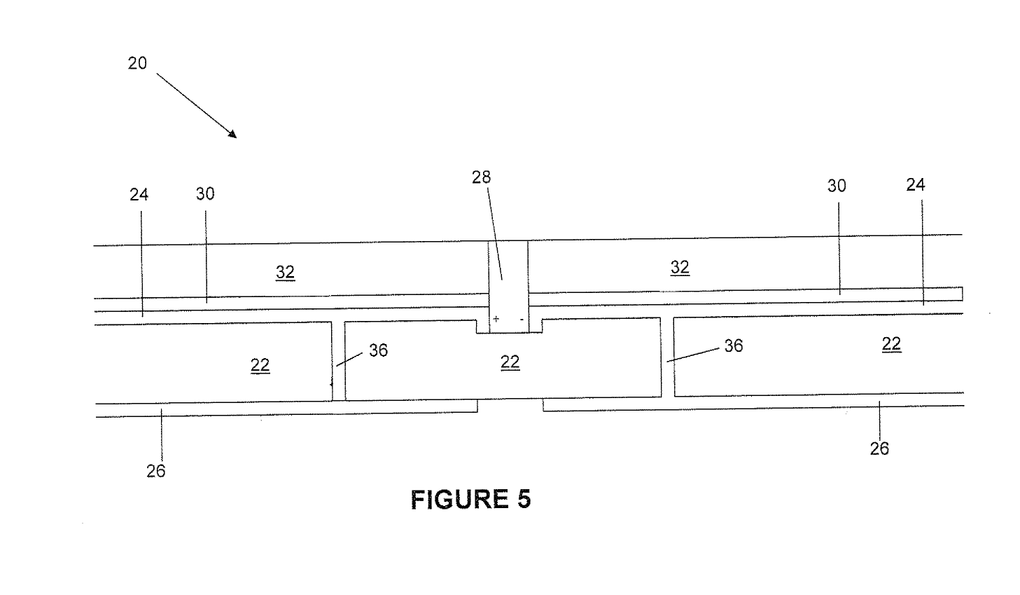

Referring again to the drawings, FIG. 5 is a cross-section of a small portion of a photovoltaic panel 20 of the present invention. Photovoltaic panel 20 is based on a planar, electrically insulating substrate sheet 22 that preferably is made of epoxy. Electrical conductors such as copper are plated by standard printed circuit board fabrication techniques on the two sides of substrate 22: upper conductors 24 on the upper side of substrate 22 and lower conductors 26 on the lower side of substrate 26. Upper conductors 24 and lower conductors 26 are connected electrically by way of vias 36 through substrate 22. A photovoltaic cell 28, with the indicated polarity, is placed in a trench in substrate 22 between two upper conductors 24 and in electrical contact with those two upper conductors 24. Preferably, photovoltaic cell 28 is a monocrystalline silicon photovoltaic cell with a surface such as a black silicon surface for efficient absorption of incident light. When photovoltaic cell 28 is illuminated with light of the appropriate wavelengths, photovoltaic cell 28 creates a voltage difference between the two upper conductors 24 that causes an electrical current to flow through the two upper conductors 24.

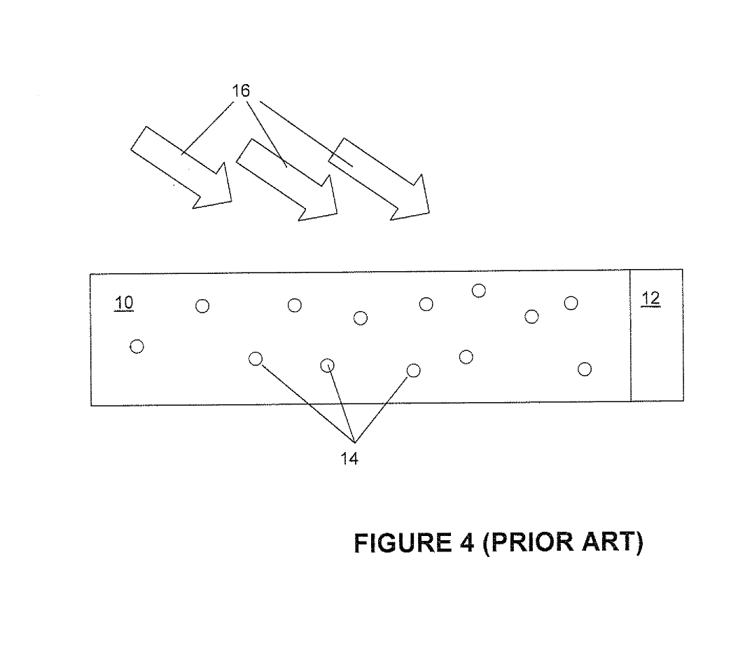

Upper conductors 24 are covered by a thin layer 30 of a diffusively reflective material that in turn is covered by a luminescent solar concentrator 32 that butts up against photovoltaic cell 28 the way luminescent solar concentrator 10 of FIG. 4 butts up against photovoltaic cell 14 of FIG. 4.

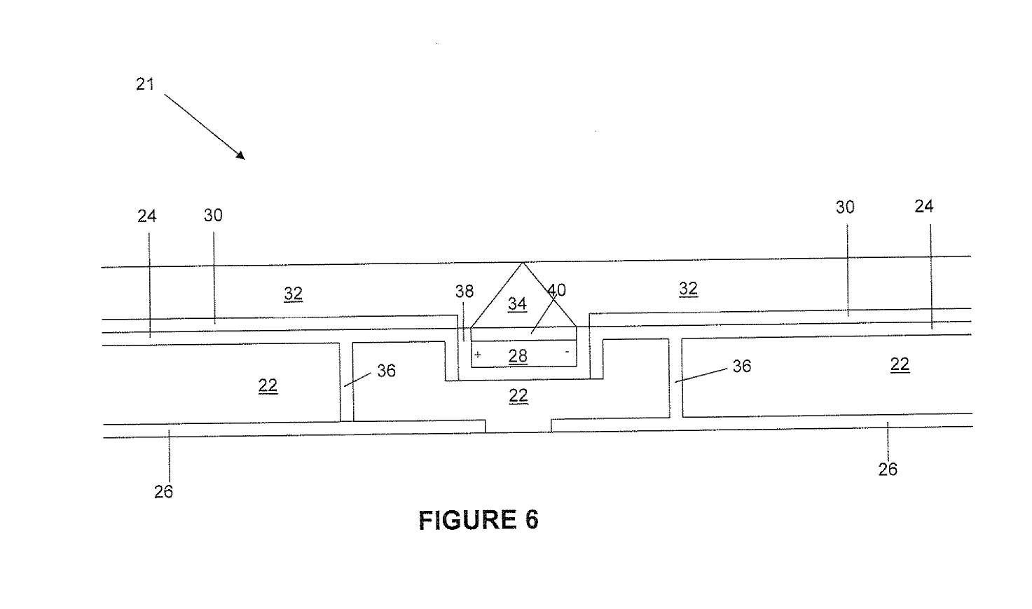

FIG. 6 is a cross-section of a small portion of another photovoltaic panel 21 of the present invention. Photovoltaic panel 21 is similar to photovoltaic panel 20, with photovoltaic cell 28 oriented horizontally instead of vertically. A pyrimidal lens 34 is provided above photovoltaic cell 28 to direct light from luminescent solar concentrator 32 down towards photovoltaic cell 28. Photovoltaic cell 28 is encapsulated in an electrically conductive encapsulation. 38 and is separated from lens 34 by vacuum 40.

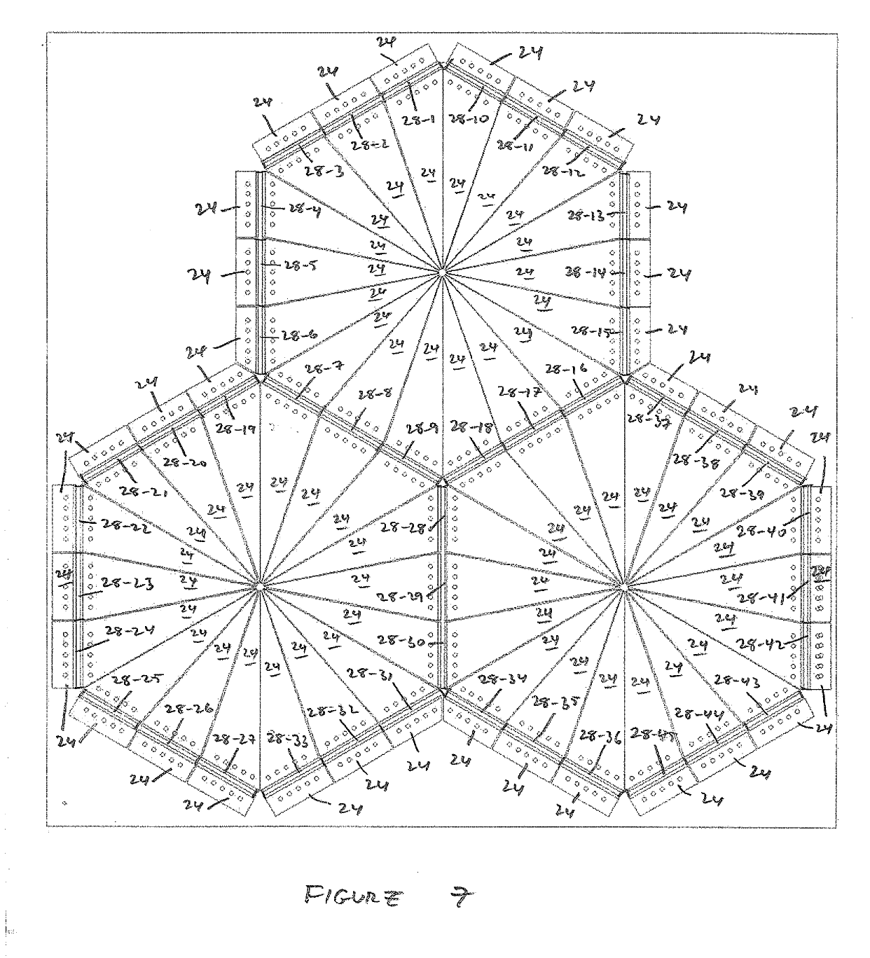

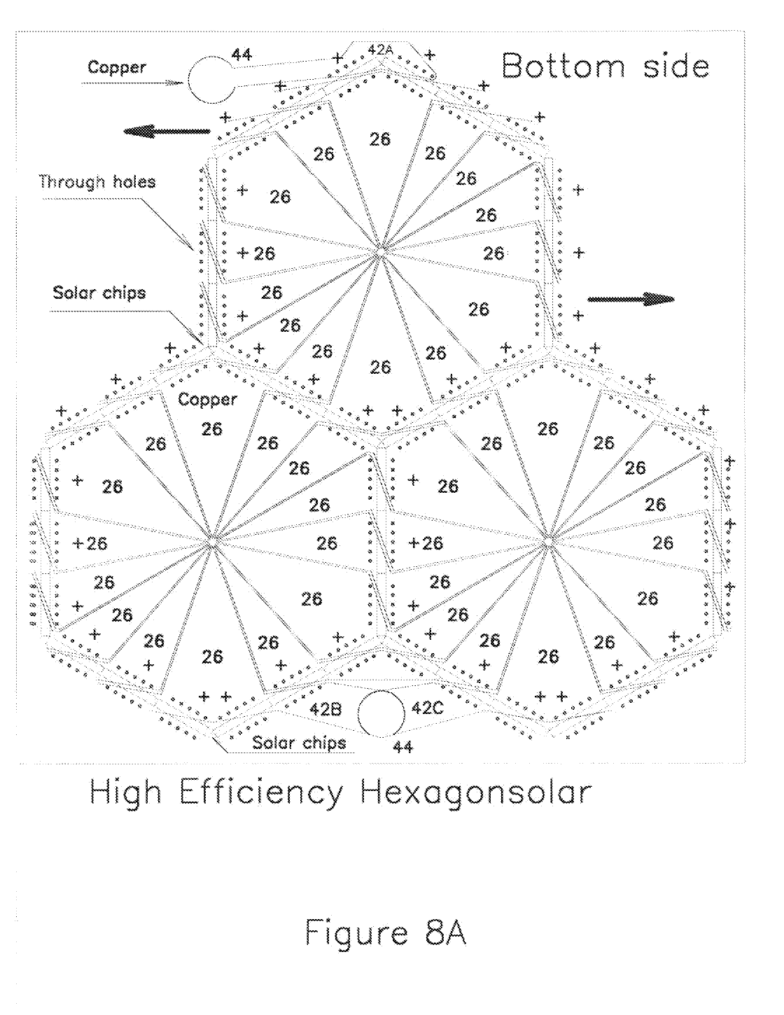

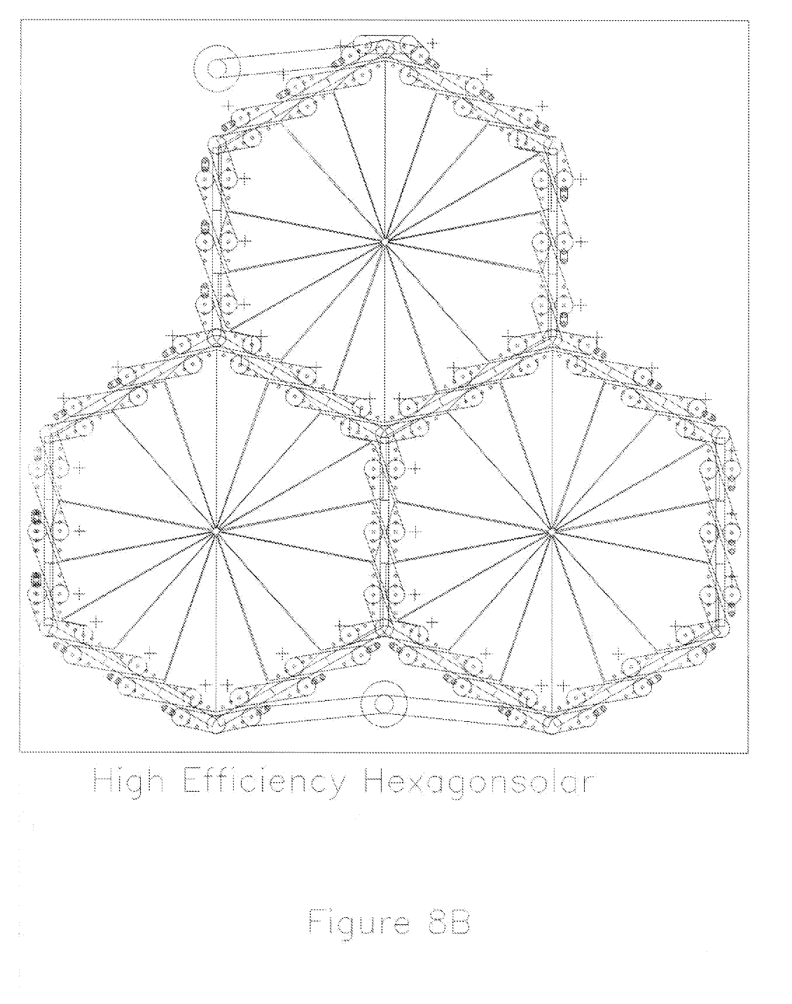

FIGS. 7 and 8A show, respectively, the layout of upper conductors 24 and lower conductors 26 in a basic photovoltaic panel 20 or 21 of the present invention. There are two kinds of upper conductors 24: triangular petals of three hexagonal flowers, and, rectangles that surround the array of the three flowers. The sides of the hexagons are about 5 cm long_45 photovoltaic cells 28, labeled “28-1” through “28-45”, are positioned between the hexagons and between the hexagons and the rectangles, as shown. The unlabeled circles in FIG. 7 represent vias 36 that connect upper conductors 24 to lower conductors 26. Lower conductors 26 are shaped so as to connect photovoltaic cells 28 in series in a manner that provides the following paths from a contact 42A adjacent to lower conductors 26 at one edge of substrate 22 to a contact 42B adjacent to lower conductors 26 at the opposite edge of substrate 22:

First path: (28-1), (28-2), (28-3), (28-4), (28-5), (28-6), (28-19), (28-20), (28-21), (28-22), (28-23), (28-24), (28-25), (28-26), (28-27)

Second path: (28-1), (28-2), (28-3), (28-4), (28-5), (28-6), (28-7), (28-8), to (28-9), (28-28), (28-29), (28-30), (28-31), (28-32), (28-33)

Third path: (28-10), (28-11), (28-12), (28-13), (28-14), (28-15), (28-16), (28-17), (28-18), (28-28), (28-29), (28-30), (28-31), (28-32), (28-33)

and from contact 42A to another contact 42C adjacent to lower conductors 26 at the opposite edge of substrate 22:

Fourth path: (28-10), (28-11), (28-12), (28-13), (28-14), (28-15), (28-37), (28-38), (28-39), (28-40), (28-41), (28-42), (28-43), (28-44), (28-45)

Fifth path: (28-10), (28-11), (28-12), (28-13), (28-14), (28-15), (28-16), (28-17), (28-18), (28-28), (28-29), (28-30), (28-34), (28-35), (28-36)

Sixth path: (28-1), (28-2), (28-3), (28-4), (28-5), (28-6), (28-7), (28-8), (28-9), (28-28), (28-29), (28-30), (28-34), (28-35), (28-36)

FIG. 8B shows the structure of lower conductors 26, as designed using standard computer-aided-design software: lower conductors 26 are individual triangular petals, similar to upper conductors 24, or pairs of such triangular petals, extended and/or joined by jumpers that appear in FIG. 8B as ovals that have circles at both ends.

Lower conductors 26 connect the negative side of each photovoltaic cell 28 in each path (except for the last photovoltaic cell 28 in the path) to the positive side of the next photovoltaic cell in the path, as shown by the “+” signs in FIGS. 8A and 8B, so that the voltages generated by photovoltaic cells 28 are added to each other along the paths. In the case of FIGS. 7, 8A and 8B, with 15 photovoltaic cells 28 in each path, the total voltage difference between contact 42A and either contact 42B or contact 42C is 15 times the voltage produced by one photovoltaic cell 28, minus resistive losses in conductors 24 and 26 and in vias 36. The electrical power generated by the photovoltaic panel is tapped via leads 44. Normally, a lead 44 is provided between adjacent pairs of contacts 42, as shown in FIG. 8A for contacts 42B and 42C.

In addition to providing the electrical connections among photovoltaic cells 28, conductors 24 and 26 also conduct heat away from photovoltaic cells 28 to keep photovoltaic cells 28 from overheating. To this end, preferably, conductors 24 and 26 are made of a material such as copper that is both an excellent electrical conductor and an excellent thermal conductor.

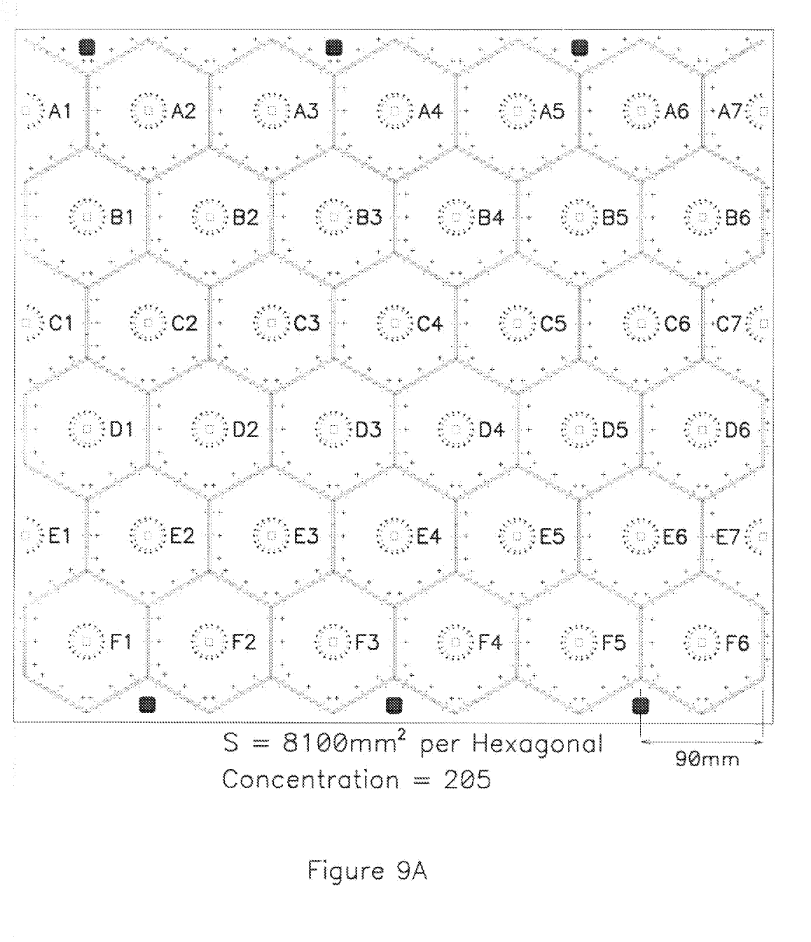

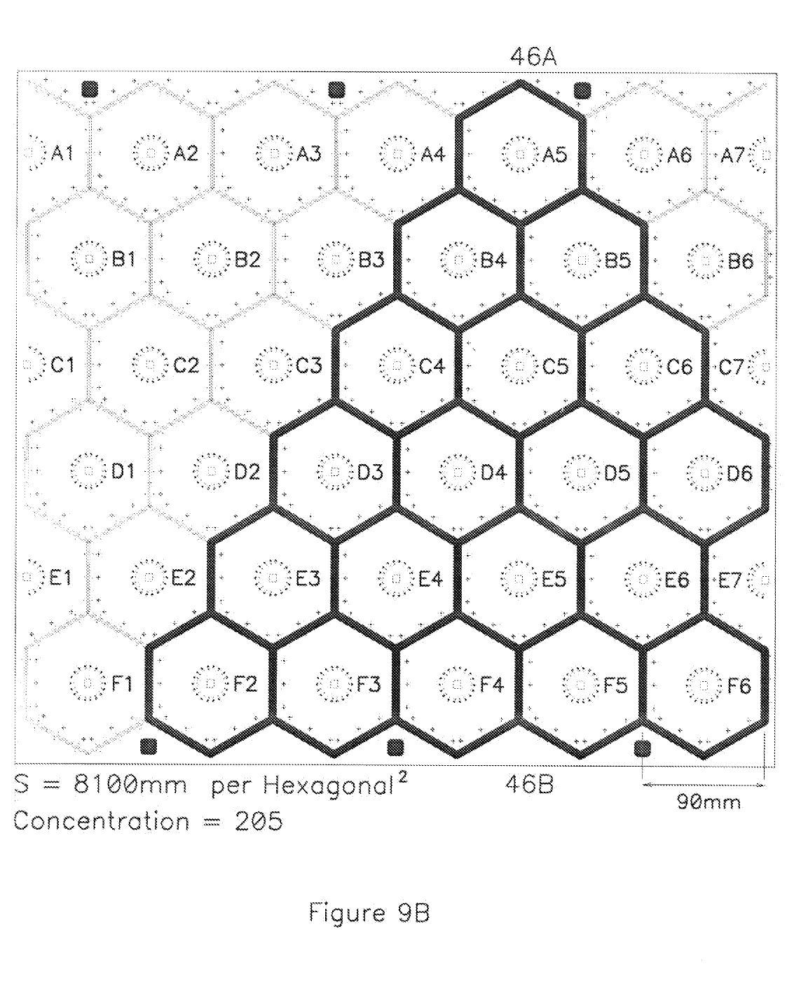

FIGS. 9A and 9B show a portion of the layout of a typical full-size photovoltaic panel 20 or 21 of the present invention. FIGS. 9A and 9B show all or part of 39 hexagons labeled “A1” through “F6”, bounded by (unlabeled) photovoltaic cells 28, and the associated leads 44 shown as black squares. The circles in the middle of the hexagons are test points for testing the connectivity of conductors 24 and 26. There are many more conductive paths from a contact at one edge 46A of such a panel to contacts at the opposite edge 46B of such a panel, as shown by the thick lines in FIG. 9B, than there are in the basic panel of FIGS. 7, 8A and 8B

A 36-hexagon panel (area of about 0.25 meters) (similar to FIG. 9A but without the hexagons labeled “A7”, “C7” and “E7”), either with vertical photovoltaic cells (panel 20) or with horizontal photovoltaic cells (panel 21), when illuminated by full sunshine, produces about 80-100 watts of DC power (about 24 volts across the panel; current of about 4 amps).

While the invention has been described with respect to a limited number of embodiments, it will be appreciated that many variations, modifications and other applications of the invention may be made. Therefore, the claimed invention as recited in the claims that follow is not limited to the embodiments described herein.

What is claimed is:

1. An electrical device comprising:
(a) an electrically insulating sheet;
(b) on a first side of said sheet:
(i) a plurality of first electrically conductive regions that are electrically isolated from each other, and
(ii) for each of at least a portion of adjacent pairs of said first electrically conductive regions: a respective electrical component that electrically connects said first electrically conductive regions of said each pair;
(c) on a second side of said sheet, a plurality of second electrically conductive regions that are electrically isolated from each other;
(d) a plurality of vias through said sheet, each said via electrically connecting one respective said first electrically conductive region to one said second electrically conductive region;
(e) at least one first electrical contact, at a first edge of said sheet, electrically connected to one of said electrically conductive region; and
(f) a plurality of second electrical contacts at a second edge of said sheet, each said second electrical contact being electrically connected to one of said electrically conductive regions;
wherein said electrically conductive regions, said components and said vias are arranged to provide an electrically conductive path between each said first electrical contact and at least two of said second electrical contacts.

2. The electrical device of claim 1, comprising a plurality of said first electrical contacts.

3. The electrical device of claim 1, wherein said electrical components include photovoltaic cells.

4. The electrical device of claim 3, wherein each said photovoltaic cell is between said first electrically conductive regions that are electrically connected by said each photovoltaic cell.

5. The electrical device of claim 3, further comprising:
(g) an optically transparent layer covering at least a portion of said first electrically conductive regions on said first side of said sheet; and
(h) for each said photovoltaic cell, a respective lens for directing, towards said each photovoltaic cell, light that emerges from said optically transparent layer.

6. The electrical device of claim 5, further comprising:
(i) a diffusely reflective layer, at least partially covering said first electrically conductive regions, between said first side of said sheet and said optically transparent layer.

7. The electrical device of claim 5, wherein said transparent layer includes a luminescent solar concentrator.

8. A photovoltaic energy panel comprising:
(a) an electrically insulating sheet;
(b) on a first side of said sheet:
(i) a plurality of first electrically conductive regions that are electrically isolated from each other, and
(ii) for each of at least a portion of adjacent pairs of said first electrically conductive regions: a respective photovoltaic cell, between said first electrically conductive regions of said each pair, that electrically connects said first electrically conductive regions of said each pair;
(c) on a second side of said sheet, a plurality of second electrically conductive regions that are electrically isolated from each other;
(d) a plurality of vias through said sheet, each said via electrically connecting one respective said first electrically conductive region to one said second electrically conductive region;
(e) at least one first electrical contact, at a first edge of said sheet, electrically connected to one of said electrically conductive region; and
(f) at least one second electrical contact at a second edge of said sheet, electrically connected to one of said electrically conductive regions;
wherein said electrically conductive regions, said photovoltaic cells and said vias are arranged to provide an electrically conductive path between each said first electrical contact and at least one of said at least one second electrical contact.

9. The electrical device of claim 8, further comprising:
(g) an optically transparent layer covering at least a portion of said first electrically conductive regions on said first side of said sheet; and
(h) for each said photovoltaic cell, a respective lens for directing, towards said each photovoltaic cell, light that emerges from said optically transparent layer.

10. The electrical device of claim 9, further comprising:
(i) a diffusely reflective layer, at least partially covering said first electrically conductive regions, between said first side of said sheet and said optically transparent layer.

11. The electrical device of claim 9, wherein said transparent layer includes a luminescent solar concentrator.

12. A photovoltaic energy panel comprising:
(a) a substantially flat substrate;
(b) at least one photovoltaic cell embedded in said substrate;
(c) an optically transparent layer covering at least a portion of said substrate; and
(d) for each said photovoltaic cell, a respective lens for directing, towards said each photovoltaic cell, light that emerges from said optically transparent layer.

13. The photovoltaic energy panel of claim 12, wherein said optically transparent layer includes a luminescent solar concentrator.

14. The photovoltaic energy panel of claim 12, further comprising:
(e) a diffusely reflective layer between said substrate and said optically transparent layer.
